(19) United States
(12) Patent Application Publication
(10) Pub. No.: US 2007/0108594 A1
(43) Pub. Date: May 17, 2007

(54) Semiconductor apparatus

(75) Inventor: Kenichi Ishii, Kawasaki (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KAWASAKI (JP)

(21) Appl. No.: 11/594,779

(22) Filed: Nov. 9, 2006

(30) Foreign Application Priority Data
Nov. 17, 2005 (JP) 2005-332887

(51) Int. Cl. H01L 23/12

(52) U.S. Cl. 257/704

(57) ABSTRACT

A semiconductor apparatus that comprises a semiconductor chip having a first surface including an external connection terminal and a second surface opposing the first surface, a cap having a recessed part that accommodates the semiconductor chip, and a bonding member for bonding the second surface of the semiconductor chip with a bottom of the recessed part of the cap. In a central region excluding corners of the second surface, the second surface of the semiconductor chip is bonded with the bottom of the recessed part of the cap by the bonding member. By an entire surface of the semiconductor chip not bonded with the cap, an influence of thermal stress from the cap can be reduced.

### BACKGROUND OF THE INVENTION

1. Field of the Invention

The present invention relates to a semiconductor apparatus for reducing thermal stress applied to a compact package mounting a chip.

2. Description of Related Art

In recent years, electric equipments are becoming to be more high performance, have more advanced functions, and miniaturized. An importance of high-density packaging technology of a semiconductor integrated circuit, a key device of this progress, has been increasing with the progress in electric equipments. A CSP (Chip Size Package) technology is developed for an implementation to support the high-density packaging of a semiconductor integrated circuit. The CSP is a package having the same size as a bare chip (hereinafter referred to as a semiconductor chip) mounting a semiconductor integrated circuit formed therein. The CSP technology is a technology to accommodate the semiconductor chip to a CSP.

As an example of CSP, a DirectFET developed by International Rectifier Corporation is disclosed in Japanese Patent Translation Publication No. 2004-500720 (corresponding to U.S. Pat. No. 6,624,522). The DirectFET helps miniaturize a power MOSFET (Metal Oxide Semiconductor Field Effect Transistor). Further, the DirectFET improves mounting property and heat dispersing property of a power MOSFET. The DirectFET is described hereinafter in detail.

FIG. 9 is a cross-sectional diagram showing a DirectFET. As shown in FIG. 9, a semiconductor chip 32 is connected with a metal cap 31 using a conductive resin 34. The metal cap 31 is formed in a container shape, slightly larger than a size of the semiconductor chip 32. External connection terminals 33 for connecting with a source or a gate electrode are formed in a semiconductor chip circuit surface 32a. A drain electrode is formed in a semiconductor chip rear surface 32b. Drain electrodes of the metal cap 31 and the semiconductor chip 32 have the same potentials due to the conductive resin 34. Further, the external connection terminals 33 and a metal cap edge surface 31a are disposed on the same surface. Therefore, a drain electrode (the metal cap edge surface 31a), a source and gate electrodes formed to the semiconductor chip circuit surface 32a are formed on the same surface. Thus a gate, a drain, and a gate terminals of the semiconductor chip 32 can be reflow and soldered at the same time to an electrode pad. Accordingly, mounting property of the semiconductor chip 32 is improved. Further, the surface of the semiconductor chip 32 of a DirectFET 30 is bonded to a printed circuit board (not shown) and the other surface of the semiconductor chip 32 of a DirectFET 30 is bonded to the metal cap 31, thereby heat dispersing property of the semiconductor chip 32 is improved.

A CSP characterized in improving heat dispersing property is also disclosed by Joshi in U.S. Pat. No. 5,789,809. The CSP disclosed by Joshi is related to a CSP developed by National Semiconductor Corporation. The CSP improves heat dispersing property by bonding a semiconductor chip to a conductive cap.

However a stress from thermal expansion and shrinkage greatly influences the semiconductor chip, especially in case the semiconductor chip generates heat such as a power MOSFET. A coefficient of linear expansion of silicon that is general material for a semiconductor chip is 3 ppm/° C., a coefficient of linear expansion of copper used for metal cap is 17 ppm/° C., a coefficient of linear expansion for glass epoxy used for printed circuit board is 20 ppm/° C., a coefficient of linear expansion for lead-free solder is 22 ppm/° C., and a coefficient of linear expansion for epoxy resin used for conductive resin material is 20 ppm/° C. With the above configuration, a large difference of coefficient of linear expansions is created between the semiconductor chip and the metal cap or the conductive resin. And also, a large difference of coefficient of linear expansions is created between the semiconductor chip and the printed circuit board or the solder.

For example in case stress caused from a temperature cycle is applied to an electronic equipment mounting a semiconductor chip, materials including the semiconductor chip repeats heat expansion and shrinkage. At this time, a large thermal stress is applied to a place where materials of a different coefficient of linear expansions join. Thus when stress caused from a temperature cycle is applied repeatedly, a strength of a bonded part of the materials is deteriorated, generating a crack in the bonded part. Consequently the semiconductor chip and the electronic equipment are badly connected and then break down.

The inventor analyzed the thermal stress applied to the abovementioned configuration using an analysis tool or the like. As a result, it has been discovered that a larger thermal stress is applied to periphery and near corners of the semiconductor chip, between the semiconductor chip and the metal cap. Thus lives of electric equipments depend on connections in periphery and near corners of the semiconductor chip. Accordingly in order to secure a long-term reliability for a product, it is necessary to reduce the aforementioned thermal stress.

### SUMMARY OF THE INVENTION

According to an aspect of the present invention, there is provided a semiconductor apparatus comprising: a semiconductor chip having a first surface including an external connection terminal and a second surface opposing the first surface; a cap having a recessed part that accommodates the semiconductor chip; and a bonding member for bonding the second surface of the semiconductor chip with a bottom surface of the recessed part of the cap, wherein the second surface is bonded with the bottom surface by the bonding member in a central region excluding corners of the second surface of the semiconductor chip.

According to a semiconductor apparatus comprising: a semiconductor chip having a first surface and a second surface opposing the first surface; a cap having a main surface and accommodating the semiconductor chip; and a bonding member for bonding the second surface of the semiconductor chip with the main surface of the cap, wherein the second surface is bonded with the main surface by the bonding member in a region excluding corners of the second surface of the semiconductor chip.

The present invention provides a semiconductor apparatus that reduces an influence of thermal stress to the semiconductor chip from the cap.

### BRIEF DESCRIPTION OF THE DRAWING

The above and other objects, advantages and features of the present invention will be more apparent from the following description taken in conjunction with the accompanying drawings, in which:

FIG. 1 is a plan view of a semiconductor apparatus and a cross-sectional diagram taken along the line I-I of the plan view according to a first embodiment of the present invention;

FIG. 2 is a plan view showing a degree of thermal stress to the semiconductor apparatus according to the first embodiment of the present invention;

FIG. 3 is a cross-sectional diagram showing an example of configuration according to the first embodiment of the present invention

FIG. 4 is a cross-sectional diagram showing another example of configuration according to the first embodiment of the present invention;

FIG. 5 is a cross-sectional diagram showing another example of configuration according to the first embodiment of the present invention;

FIG. 6 is a view showing another example of configuration and a cross-sectional diagram taken along the line II-II of the plan view according to the first embodiment of the present invention;

FIG. 7 is a view showing another example of configuration and a cross-sectional diagram taken along the line III-III of the plan view according to the first embodiment of the present invention;

FIG. 8 is a view showing a semiconductor apparatus and a cross-sectional diagram taken along the line IV-IV of the plan view according to a second embodiment of the present invention; and

FIG. 9 is a cross-sectional diagram showing a semiconductor apparatus according to a conventional technique.

### DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

### First Embodiment

A preferred embodiment of the present invention is described hereinafter in detail. The explanation and drawings below are omitted and simplified as appropriate for clarity. Further, the explanation will not be repeated for clarity.

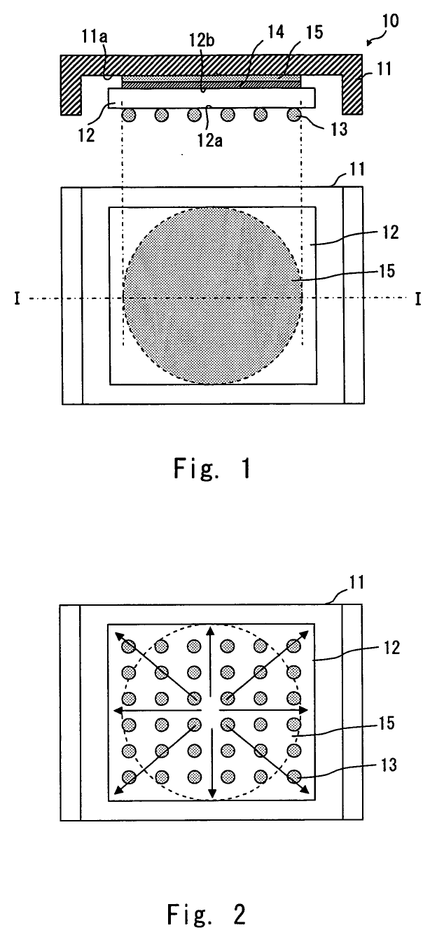

A first embodiment of the present invention is described hereinafter in detail with reference to the drawings. FIG. 1 is a plan view showing a semiconductor apparatus 10 and a cross-sectional diagram taken along the line I-I of the plan view according to this embodiment. As shown in FIG. 1, the semiconductor apparatus 10 has a conductive cap 11 and a semiconductor chip 12. The conductive cap 11 is formed by metal. External connection terminals 13 are formed in a semiconductor chip circuit surface 12a. A semiconductor chip rear surface 12b is metallized with a conductive material 14(herein after referred to as a matallized material 14). Further, a conductive cap bottom surface (main surface) 11a is electrically connected with the semiconductor chip rear surface 12b by a solder 15.

In this embodiment, the semiconductor chip 12 is a bear chip including MOSFET formed therein. The bear chip is about two or three mm size, diced from a wafer where MOSFET devices are formed in a silicon substrate. The bear chip is bonded to the conductive cap 11, which is slightly larger than a size of the chip. This creates a CSP having a size close to the size of the chip. Thereby, it is possible to mount it easily without reducing packaging density.

The conductive cap 11 is a container for the semiconductor chip 12. And the conductive cap 11 has a recessed part that accommodates the semiconductor chip 12. The conductive cap 11 has a base portion and a side portion. The side portion extends from the base portion. The side portion is formed separately on the base portion. The conductive cap bottom surface 11a is a surface of the base portion and substantially flat. And the conductive cap bottom surface 11a is defined by the side portion. The semiconductor chip 12 is mounted on the bottom surface 11a. In other words, the, conductive cap bottom surface 11a is a surface for mounting the semiconductor chip 12. The conductive cap 11 is formed of metal such as copper(Cu), aluminum(Al), and kovar. A surface of the conductive cap 11 is covered with nickel, solder, or gold, for example. Further, it may be formed by a conductive resin combining conductive filler such as carbon.

The external connection terminals 13 of the semiconductor chip circuit surface 12a are connected with a source and gate electrodes of a MOSFET formed in the semiconductor chip 12. For example BGA (Ball Grid Array) is formed by solder ball. Connecting the BGA to the electrode pad formed on the printed circuit board and the like realizes a high-density wiring. Fluxless solder or lead-free solder is suitable for the solder ball material. Not only the solder but also gold bump may be used or ACF (Anisotropic Conductive Film) may be combined to support for a flip chip connection.

The metallized material 14 is formed on the semiconductor chip rear surface 12b for securing a conductivity between the circuit formed in the semiconductor chip 12 and the conductive cap 11. Accordingly the metallized part works as an electrode for connecting an electric circuit formed in the semiconductor chip 12 and the conductive cap 11. As a preferred example, it is used for a drain contact of a MOSFET formed in the semiconductor chip 12. That is, the conductive cap 11 also functions as an external connection terminal.

Further, the abovementioned metallized material 14 may be formed to radiate heat that is generated in the semiconductor chip 12 to the conductive cap 11. In this case, the electric circuit formed in the semiconductor chip 12 needs not to be electrically connected to the metallized material 14. As described in the foregoing, the bonding between the conductive cap 11 and the semiconductor chip 12 is not only purposed to mechanically fix them but also purposed to electrically connect them and radiate heat.

In this embodiment, the metallized material 14 is formed on a central part of the semiconductor chip rear surface 12b, having an almost circular shape inscribing the semiconductor chip rear surface 12b. Solder bonding between the semiconductor chip 12 and the conductive cap 11 is made on the metallized material 14 where solder alloy is formed. Accordingly the bonded part between the semiconductor chip 12 and the conductive cap 11 is almost circular shape. Further, outside area of the metallized material 14 on the semiconductor chip rear surface 12b is not metallized and exposing. Thus the solder 15 does not touch with the corners and peripheral parts of the semiconductor chip 12b and cannot be bonded therewith. As a result, a gap is generated having a thickness of the solder 15 and metallized material 14 between the semiconductor chip 12 and the conductive cap 11.

Hereinafter, a degree of the thermal stress caused by the temperature cycle is described in detail. Incidentally, temperature cycle is conducted by turning ON or OFF a thermal test device. FIG. 2 is a plan view showing the degree of the thermal stress generated in the semiconductor apparatus 10 according to this embodiment. Arrows indicate a magnitude of the thermal stress applied to the semiconductor apparatus 10. As shown in FIG. 2, the degree of the thermal stress increases as moving away from a center.

Materials expand when heated and shrink when cooled. When restraining deformation of the materials and giving thermal change to the materials, a distortion is generated due to the thermal change because an amount of deformation that meant to be generated is restrained. Assuming that a coefficient indicating a degree of expansion due to the thermal change is a coefficient of linear expansion α, a size of the material is S, and a temperature difference ΔT, the amount of deformation λ (amount of distortion) can be calculated as λ=α×S×ΔT. That is, the amount of distortion is proportional to the size of the material S. Accordingly the amount of distortion in the corners and peripheral parts that are distant from the center of the semiconductor chip is large, thereby having a larger degree of thermal stress.

In this embodiment, an almost circular region indicated with dotted line of FIG. 2 is a solder bonded region between the semiconductor chip 12 and the conductive cap 11. With the almost circular shape of the bonded region, the solder does not reach the corners and peripheral parts of the semiconductor chip. This prevents a large distortion to be generated. Furthermore, the shape of the bonded region is desirably the almost circular shape, however it may be an oval or a polygon without corners. The bonded region of the almost circular shape is not limited to only one part but a plurality of the bonded regions may be formed in the semiconductor chip rear surface 12a.

The smaller the bonded region is, the smaller the thermal stress generated in the bonded part of the semiconductor chip 12 and the solder 15. However to secure a bonding strength, electronic connectivity, and heat dispersing property, a certain size of a bonded region is required. Accordingly a proportion of the bonded region size on the semiconductor chip rear surface 12 area is preferably as high as possible, at least 50 percent, appropriately at least 70 percent.

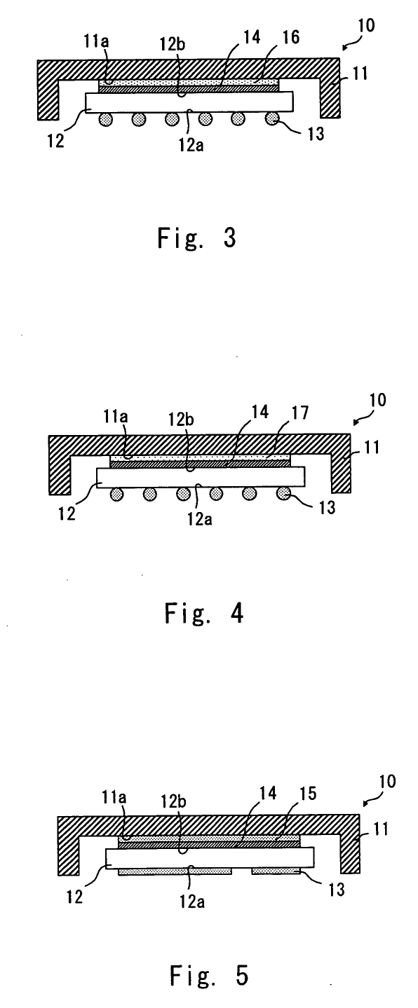

Another example of configuration according to the first embodiment is described hereinafter in detail with reference to FIG. 3. In FIG. 3, the conductive cap 11 is bonded with the semiconductor chip rear surface 12b by a conductive adhesive 16. Other components are identical to those in FIG. 1, thus the explanation shall not be repeated. The conductive adhesive 16 is an adhesive resin having thermal conductive particulates (thermal conductive filler). The conductive adhesive 16 has natures of conducting heat and adhering materials.

Epoxy resin is often used for adhesive resin of the conductive adhesive 16. However silicon, polyimide, acrylic, or polyurethane and the like may be used. Further, the conductive filler is often combined with silver but carbon and copper and the like may be used. In general, the conductive adhesive 16 has higher elastic coefficient and stretch property. With the conductive filler combined therein, the conductive adhesive 16 has high thermal conductivity.

FIG. 4 is a cross-sectional diagram showing another configuration of the first embodiment. In FIG. 4, the conductive cap 11 and the semiconductor chip rear surface 12b are bonded with a thermal conductive adhesive 17. Other components are identical to those in FIG. 1, thus the explanation shall not be repeated. The thermal conductive adhesive 17 is a adhesive resin having thermal conductive particulates (thermal conductive filler). The thermal conductive adhesive 17 has natures of transferring heat and adhering materials in an insulated condition.

Epoxy resin is often used for adhesive resin of the thermal conductive adhesive 17. However silicon, polyimide, acrylic, or polyurethane and the like may be used. The thermal conductive filler is often combined with silica, however alumina or aluminum nitride may also be used.

This embodiment is preferably used for a case that the semiconductor chip 12 and the conductive cap 11 need to be insulated. Accordingly the conductive cap 11 in this example is used as a heat sink, not as an external connection terminal. The thermal conductive adhesive 17 has higher elastic coefficient and stretch property than the solder 15 as with the conductive adhesive 16. With the thermal conductive filler contained therein, the thermal conductive adhesive 17 has high thermal conductivity.

FIG. 5 is a cross-sectional diagram showing another configuration of the first embodiment. This embodiment may especially be used for a case electrode pads of the printed circuit board that mounts the semiconductor apparatus 10 are not formed in array. The external connection terminals 13 of a circuit which are formed on a side of the semiconductor chip have a pattern shape corresponding to a footprint or pad etc of the print circuit board for connecting the semiconductor apparatus 10. Other components are identical to those in FIG. 1. However for the bonding material of the semiconductor chip 12 and the conductive cap 11, the conductive adhesive 16 and the thermal conductive adhesive 17 may be used instead of the solder 15.

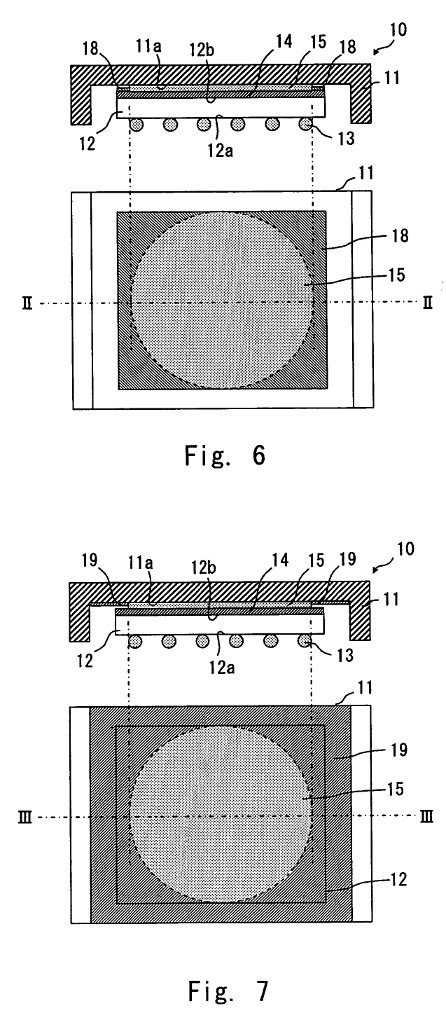

FIG. 6 is a plan view showing another configuration of the first embodiment and a cross-sectional diagram thereof. This embodiment may especially be used for a case the metallized material 14 of the semiconductor chip rear surface 12b is not formed in an almost circular shape. In this embodiment, insulated resin 18 is previously coated on the metallized material 14. Insulated resin 18 is provided on a region excluding the bonded region between the semiconductor chip rear surface 12b and the conductive cap 11. An order of bonding is described hereinafter. Firstly an outside of the bonded region having the almost circular shape formed on the semiconductor chip rear surface 12b is coated with the insulated resin 18. After the insulated resin 18 is dried, the bonded region between the semiconductor chip 12 and the conductive cap 11 is joined by solder.

For example in a case an entire surface of the semiconductor chip rear surface 12b is coated by metallized material 14, it is difficult to solder only to the bonded region having the almost circular shape that is formed on the semiconductor chip rear surface 12b, because the solder 15 could overflow. Accordingly by coating a region outside the bonded region with the insulating resin 18, the solder 15 can be prevented from overflowing to outside of the bonded region.

The insulated resin 18 used in this example is preferably polyimide resin. However silicon, epoxy, and polyurethane and the like may be used. For the bonding material of the semiconductor chip 12 and the conductive cap 11, the conductive adhesive 16 or the thermal conductive adhesive 17 may be used instead of the solder 15. In this case, the bump of the insulated resin 18 helps preventing from overflowing the conductive adhesive 16 and the thermal conductive adhesive 17. Further, the external connection terminals 13 of the semiconductor chip 12 may not only be formed in array but in a shape corresponding to a pattern of the print circuit board which are connected to the external connection terminals 13.

FIG. 7 is a plan view showing another configuration of the first embodiment and a cross-sectional diagram thereof. In this example, an insulating material 19 is coated on a rear surface of the conductive cap 11. The insulating material 19 is formed surrounding the bonded region on the semiconductor chip 12. The insulating material may be coated by an oxide film treatment or the insulating material can be an insulating resin such as solder resist.

For example as shown in FIG. 7 in which an entire surface of the semiconductor chip rear surface 12b is coated with the metallized material 14, it is difficult to solder only to the bonded region having the almost circular shape that is formed on the semiconductor chip rear surface 12b, because the solder 15 could overflow. Accordingly by coating a region of the conductive cap 11 side which surrounds the bonded region, the solder 15 can be prevented from overflowing to outside of the bonded region of the semiconductor chip rear surface 12b.

For the bonding material of the semiconductor chip 12 and the conductive cap 11, the conductive adhesive 16 or the thermal conductive adhesive 17 may be used instead of the solder 15. In this case, a condition of the surfaces created by oxide film treatment or a bump by solder resist can prevent the conductive adhesive 16 and the thermal conductive adhesive 17 from overflowing. The external connection terminals 13 of the semiconductor chip 12 may not only be formed in array but may be formed to correspond with a pattern of the printed circuit board for connecting the external connection terminals 13.

### Second Embodiment

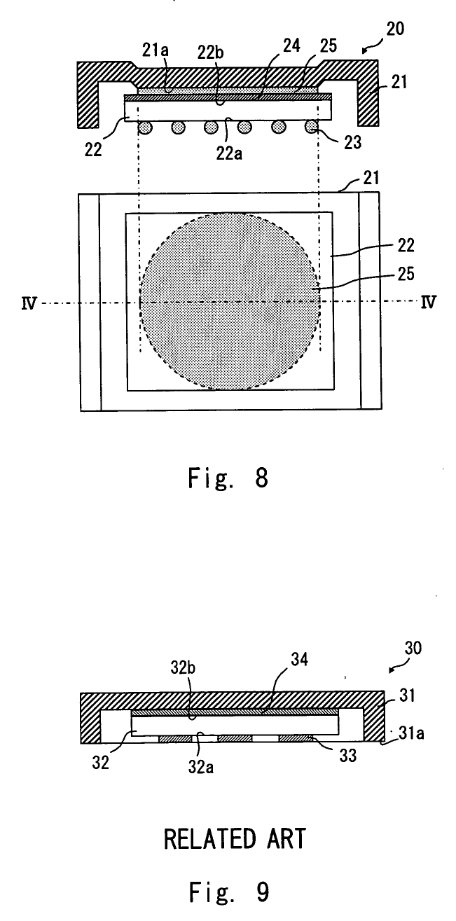

A second embodiment of the present invention is described hereinafter in detail. FIG. 8 is a plan view of a semiconductor apparatus 20 and a cross-sectional diagram taken along the line IV-IV of the plan view. As shown in FIG. 8, the semiconductor apparatus 20 comprises a conductive cap 21 and a semiconductor chip 22. External connection terminals 23 are formed on a semiconductor chip circuit surface 22a. A semiconductor chip rear surface 22b is coated with a conductive material 24 (hereinafter referred to as metallized material 24). Further, a conductive cap bottom surface 21a and a semiconductor chip rear surface 22b are electrically connected by a solder 25.

As shown the plan view of FIG. 8, a bonded part between the conductive cap 21 and the semiconductor chip 22 is indicated with dotted line having an almost circular shape. This bonded region is almost circular shape formed on a central part of the semiconductor chip rear surface 22b. The bonded region inscribes the semiconductor chip rear surface 22b. The conductive cap 21 has a projecting portion toward the semiconductor chip 22 in the bottom surface 21a. This projecting portion is formed correspond to the bonded region. That is, there is an uneven surface formed in the bottom surface 21a of the conductive cap 21 corresponding to the bonded region.

Accordingly the conductive cap 21 and the semiconductor chip 22 are soldered in the bonded region. At this time, the solder 25 will not overflow to outside of the bonded region due to the projecting portion of the conductive cap 21, even through an entire region of the semiconductor chip rear surface 22b is metallized. In FIG. 8, the projecting portion having an almost circular shape is formed corresponding to the bonded region.

A shape of the projecting portion corresponds to the shape of the bonded region, and is desirably an almost circular shape. However the shape may be an oval or a polygon without corners. Further, conductive adhesive or thermal conductive adhesive may be used for the bonding material of the semiconductor chip 22 and the conductive cap 21. The external connection terminals 23 of the semiconductor chip 22 is not limited to be formed in array, but may be a form corresponding to a pattern of the printed circuit board that connects the external connection terminals 34.

As described in the foregoing, by disposing the bonded region to a central region excluding corners and peripheral parts of the semiconductor chip (an almost circular region inscribing the semiconductor chip), thermal stress applied to a bonded part between the semiconductor chip and the conductive cap can be reduced. That is, thermal stress is not directly applied to the corners and peripheral parts of the semiconductor chip. According to the thermal stress analysis of the semiconductor apparatus configured as above conducted by the inventor, it has been found that the thermal stress is reduced by approximately 30 percent as compared to a conventional case in which the bonded region is an entire surface of a semiconductor chip. Thus the present invention improves reliability for temperature cycle stress in a bonded part between the semiconductor chip and the conductive cap.

Furthermore, by using the conductive adhesive having high elastic coefficient and stretch property in bonding the semiconductor chip and the conductive cap, the thermal stress caused by the temperature cycle stress can further be reduced. As the conductive adhesive has a high thermal conductivity, there is no problem in radiating heat generated according to the power consumption of the semiconductor chip to the conductive cap.

Further, by using the thermal conductive adhesive having high elastic coefficient and stretch property in bonding the semiconductor chip and the conductive cap, the thermal stress by the temperature cycle stress can further be reduced. As the thermal conductive adhesive has a high thermal conductivity, there is no problem in radiating heat generated by power consumed in the semiconductor chip to the conductive cap.

For the external connection terminals of the semiconductor chip, by forming a pattern corresponding to footprint or pad etc of the printed circuit board that the semiconductor apparatus is connected thereto, it is possible to connect to a pattern other than a pattern formed in array.

Furthermore, by forming an insulating resin on the surface of the semiconductor chip with its shape almost circular corresponds to the bonded region to be formed, the bonded region can be formed almost circular shape. Accordingly the bonding material is not extended to the corners and peripheral parts of the semiconductor chip, thereby reducing the thermal stress to the corners and peripheral parts of the semiconductor chip.

Similarly, by forming an insulating resin on the surface of the conductive cap with its shape surrounding the almost circular bonded region to be formed, the bonded region can be formed almost circular shape. Accordingly the bonding material is not extended to the corners and peripheral parts of the semiconductor chip, thereby reducing the thermal stress to the corners and peripheral parts of the semiconductor chip.

Similarly by providing a projecting portion having an almost circular shape corresponds to the bonded region, the bonded region can be formed almost circular shape. Therefore, the bonding material is not extended to the corners and peripheral parts of the semiconductor chip, thereby reducing the thermal stress to the corners and peripheral parts of the semiconductor chip.

In case of connecting the semiconductor apparatus of the present invention to a mother board of a printed circuit board and the like, a large thermal stress is generated in connection parts between a semiconductor chip and a conductive cap, and between the semiconductor chip and the printed circuit board. With the configuration as above, having a small thermal stress to the bonded part between the semiconductor chip and the conductive cap enables to reduce thermal stress applied to a semiconductor apparatus as compared to a conventional technique, and also secure long-term reliability of a product.

The present invention is not limited to the above embodiment but various changes and modifications can be made within the spirit and scope of the present invention. For example a thermal conductive resin can be filled inside the conductive cap. The semiconductor chip is not limited to MOSFET devices but may be applied to other semiconductor integrated circuits. Further, the present invention can be applied to a chip formed by vulnerable ceramic, for example, and not only to the semiconductor chip.

It is apparent that the present invention is not limited to the above embodiment and it may be modified and changed without departing from the scope and spirit of the invention.

What is claimed is:

1. A semiconductor apparatus comprising:
a semiconductor chip having a first surface including an external connection terminal and a second surface opposing the first surface;
a cap having a recessed part that accommodates the semiconductor chip; and
a bonding member for bonding the second surface of the semiconductor chip with a bottom surface of the recessed part of the cap,
wherein the second surface is bonded with the bottom surface by the bonding member in a central region excluding corners of the second surface of the semiconductor chip.

2. The semiconductor apparatus according to claim 1, wherein the second surface is bonded with the bottom surface by the bonding member in the central region excluding peripheral part of the second surface of the semiconductor chip.

3. The semiconductor apparatus according to claim 2, wherein the central region is an almost circular shape.

4. The semiconductor apparatus according to claim 3, wherein the central part is an almost circular shape inscribing at least two sides of the second surface of the semiconductor chip.

5. The semiconductor apparatus according to claim 1, wherein a metal electrode for soldering is formed on the second surface of the semiconductor chip in a bonded region where the semiconductor and the cap are bonded by the bonding member.

6. The semiconductor apparatus according to claim 1, wherein a resist of an insulating material is disposed on the second surface of the semiconductor chip in a region excluding a bonded region where the semiconductor chip and the cap is bonded by the bonding member.

7. The semiconductor apparatus according to claim 1, wherein an insulating material is disposed on the bottom surface of the cap in a region excluding a bonded region where the semiconductor chip and the cap is bonded by the bonding member.

8. The semiconductor apparatus according to claim 1, wherein a projecting portion toward the semiconductor chip is formed in the bottom surface of the cap and the projecting portion is formed corresponds to a bonded region where the semiconductor chip and the cap is bonded by the bonding member.

9. The semiconductor apparatus according to claim 1, wherein the bonding member is a solder material.

10. The semiconductor apparatus according to claim 1, wherein the bonding member is a conductive adhesive.

11. The semiconductor apparatus according to claim 1, wherein the bonding member is a thermal conductive adhesive.

12. A semiconductor apparatus comprising:
a semiconductor chip having a first surface and a second surface opposing the first surface;
a cap having a main surface and accommodating the semiconductor chip; and
a bonding member for bonding the second surface of the semiconductor chip with the main surface of the cap,
wherein the second surface is bonded with the main surface by the bonding member in a region excluding corners of the second surface of the semiconductor chip.
